(19) United States
(12) Patent Application Publication
(10) Pub. No.: US 2025/0203924 A1
(43) Pub. Date: Jun. 19, 2025

(54) SEMICONDUCTOR DEVICE, METHOD OF MANUFACTURING SEMICONDUCTOR DEVICE, AND POWER CONVERSION APPARATUS

(71) Applicant: Mitsubishi Electric Corporation, Tokyo (JP)

(72) Inventors: Motoru YOSHIDA, Tokyo (JP); Kohei ADACHI, Tokyo (JP); Yutaka FUKUI, Tokyo (JP); Takaaki TOMINAGA, Tokyo (JP); Akifumi IIJIMA, Tokyo (JP); Kazuya ISHIBASHI, Tokyo (JP)

(73) Assignee: Mitsubishi Electric Corporation, Tokyo (JP)

(21) Appl. No.: 18/902,827

(22) Filed: Sep. 30, 2024

(30) Foreign Application Priority Data
Dec. 19, 2023 (JP) 2023-213734

(51) Int. Cl. H01L 29/78; H01L 21/265; H01L 21/3065; H01L 29/66

(52) U.S. Cl. CPC H10D 30/668; H01L 21/26506; H01L 21/3065; H10D 30/0297

(57) ABSTRACT

A semiconductor device includes a drift layer, a p-type base layer, an n-type source layer, and a gate electrode. The base layer is formed on a part of the surface layer of the drift layer. The source layer is formed on a part of the surface layer of the base layer. The gate electrode is provided in a plurality of trenches, each penetrating the source layer and the base layer, via a gate insulating film. The source layer formed between the plurality of trenches is shallower and has a lower impurity concentration as being farther from the sidewall of each of the plurality of trenches.

### BACKGROUND OF THE INVENTION

### Field of the Invention

The present disclosure relates to a technique to suppress warpage of a semiconductor wafer caused by impurity ion implantation.

### Description of the Background Art

A power semiconductor device generally called a power device is used for a switching element that controls power supply to a motor load or the like, or the like. The power device is required to have several performances, and one of the greatest requirements of them is a reduction in loss. The reduction in loss for the power device has effects such as miniaturization and weight reduction of an apparatus, and in a broad sense, has an effect that leads to consideration for the global environment by reducing energy consumption. Furthermore, these characteristics are required to be realized at as low costs as possible.

As a power semiconductor element that satisfies these requirements, insulated gate semiconductor devices, such as insulated gate bipolar transistors (IGBTs) or metal oxide semiconductor field effect transistors (MOSFETs), are widely used.

Conventionally, as a method of reducing loss in insulated gate semiconductor devices, there is a method of increasing a channel density, and a structure called a trench type is proposed as one of the structures corresponding to this method (e.g., Japanese Patent Application Laid-Open No. 2018-117016).

For the trench type MOSFET, a configuration, in which in order to realize a narrow pitch toward a reduction in on-resistance, an interlayer insulating film is embedded inside a trench, is conceivable. In order to embed an interlayer insulating film inside a trench, however, it is necessary to form the trench deeper than before by the depth of the interlayer insulating film inside the trench. Accordingly, a source layer as a channel formation layer also needs to be formed deeper, and thus it is necessary to increase ion implantation energy for forming the source layer. As a result, there is a problem that warpage of a semiconductor wafer becomes large after the ion implantation.

### SUMMARY

An object of the present disclosure is to suppress warpage of a semiconductor wafer caused by impurity ion implantation for forming a channel formation layer in contact with the sidewall of a trench.

A semiconductor device of the present disclosure includes a drift layer, a base layer of a second conductivity type, a channel formation layer of a first conductivity type, and a gate electrode. The base layer is formed on a part of the surface layer of the drift layer. The channel formation layer is formed on a part of the surface layer of the base layer. The gate electrode is provided in a plurality of trenches, each penetrating the channel formation layer and the base layer, via a gate insulating film. The channel formation layer formed between the plurality of trenches is shallower and has a lower impurity concentration as being farther from the sidewall of each of the plurality of trenches.

The semiconductor device of the present disclosure includes the channel formation layer that is shallower and has a lower impurity concentration as being farther from the sidewall of each of the plurality of trenches. Such a channel formation layer can be formed with low implantation energy by performing ion implantation from an oblique direction with respect to the sidewall of each of the trenches. Therefore, warpage of the semiconductor after the ion implantation for forming the channel formation layer can be suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a semiconductor device according to a first preferred embodiment;

FIG. 2 is a plan view mainly illustrating a silicon carbide semiconductor portion of the semiconductor device according to the first preferred embodiment;

FIG. 3 is an enlarged view of a region R1 in FIG. 2;

FIG. 4 is a cross-sectional view, taken along line A-A in FIG. 3;

FIG. 5 is an enlarged view of a region R2 in FIG. 4;

FIG. 6 is a flowchart illustrating a manufacturing process of the semiconductor device according to the first preferred embodiment;

FIG. 7 is a cross-sectional view illustrating a state in which a drift layer is formed on a semiconductor substrate;

FIG. 8 is a cross-sectional view illustrating a state in which a base layer is formed on a surface layer of the drift layer;

FIG. 9 is a cross-sectional view illustrating a state in which a trench that penetrates the base layer to reach the drift layer is formed;

FIG. 10 is a cross-sectional view illustrating a state in which a source layer is formed on a surface layer of the base layer and a sidewall of the trench by oblique ion implantation;

FIG. 11 is a cross-sectional view illustrating a state in which the depth of the source layer is adjusted by the thickness of an oxide film mask;

FIG. 12 is a cross-sectional view illustrating a state in which the depth of the source layer is adjusted by an etching amount of a SiC surface;

FIGS. 13 and 14 are cross-sectional views illustrating a method of manufacturing a semiconductor device of a comparative example;

FIG. 15 is a view in which the amounts of warpage of semiconductor wafers are compared between the comparative example and the present preferred embodiment;

FIG. 16 is a cross-sectional view of a semiconductor device according to a second preferred embodiment;

FIG. 17 is a flowchart illustrating a manufacturing process of the semiconductor device according to the second preferred embodiment; and

FIG. 18 is a block diagram illustrating a configuration of a power conversion system according to a third preferred embodiment.

### DESCRIPTION OF THE PREFERRED EMBODIMENTS

In the following description, a first conductivity type is defined as an n-type and a second conductivity type as a p-type, but conversely, the first conductivity type may be defined as a p-type and the second conductivity type as an n-type.

### A. First Preferred Embodiment

### A-1. Configuration

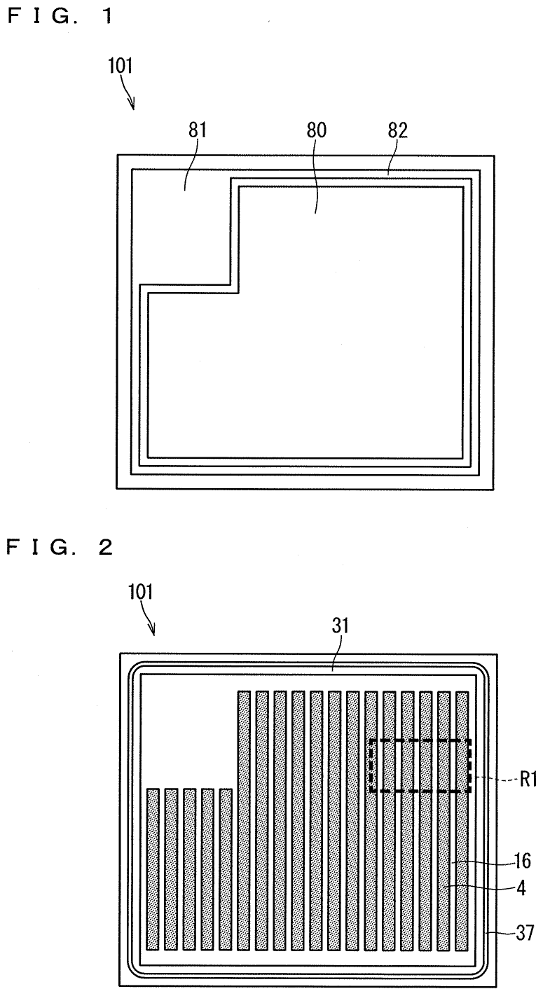

FIG. 1 is a plan view of a semiconductor device 101 according to a first preferred embodiment as viewed from above. Hereinafter, the semiconductor device 101 will be described as a MOSFET, but the semiconductor device 101 may be another switching element such as an IGBT. A semiconductor substrate may be a normal semiconductor wafer, an epitaxial growth layer, or a combination thereof. The semiconductor device 101 is formed using the semiconductor substrate made of silicon carbide (SiC). However, the material of the semiconductor substrate is not limited to silicon carbide, and may be silicon (Si) or other wide bandgap semiconductors such as gallium nitride (GaN)-based materials, gallium oxide, and diamond. Note that, of the configurations of the upper surfaces of the semiconductor device 101, a gate insulating film, a field insulating film, an interlayer insulating film, a gate electrode, a protective film, and the like are not illustrated in FIG. 1 for convenience.

In FIG. 1, a gate pad 81 is formed on a part of the upper surface of the semiconductor device 101, and a source electrode 80 is formed adjacent thereto. A gate wire 82 is formed to extend from the gate pad 81. Note that the gate pad 81 may be provided in any location of the upper surface of the semiconductor device 101. It may be provided, for example, at the center. In addition, control pads other than the gate pad 81 may be provided on the upper surface of the semiconductor device 101. The control pads other than the gate pad 81 include, for example, at least one of a current sensing pad, a Kelvin source pad, and a temperature sensing diode pad.

Next, the current sensing pad, the Kelvin source pad, and the temperature sensing diode pad will be described. The current sensing pad is a control pad for detecting a current flowing through a cell region of the semiconductor device 101. The current sensing pad is electrically connected to the cell region of the semiconductor device 101, and when a current flows through the cell region, a current, which is one in several to one in tens of thousands of the current flowing through the entire region, flows through the current sensing pad. The Kelvin source pad is a control pad to which a gate drive voltage for controlling on-off of the semiconductor device 101 is applied.

The temperature sensing diode pad is a control pad electrically connected to an anode and a cathode of a temperature sensing diode provided in the semiconductor device 101. The voltage between the anode and the cathode of the temperature sensing diode provided in the cell region is measured via the temperature sensing diode pad, and the temperature of the semiconductor device 101 is measured based on the voltage. Note that the control pads other than the gate pad 81 may be provided in any locations of the upper surface of the semiconductor device 101. They may be provided, for example, at the end or the center.

FIG. 2 is a plan view mainly illustrating a silicon carbide semiconductor portion of the semiconductor device 101. In FIG. 2, unit cell regions each including a p-type base layer 16 and a trench gate 4 having a trench type gate electrode are arranged in a stripe shape. In other words, the unit cell regions are repeatedly arranged in one direction in plan view. The semiconductor device 101 having such an arrangement of the unit cell regions is referred to as a stripe type. Note that the arrangement of the unit cell regions in the semiconductor device 101 is not limited to the stripe type. It may be another arrangement such as a lattice type or a hexagonal type.

Trench sources each having a trench-type source electrode may be provided alternately with the trench gates 4. The trench gate 4 and the trench source are collectively referred to as an active trench. A region, where the unit cell regions constituting the MOSFET are repeatedly arranged, is referred to as an active region, and a region formed at the outer periphery of the active region is referred to as a terminal region. The terminal region includes a p-type terminal well region 31, a JTE region 37 holding a withstand voltage, and the gate pad 81.

A field limiting ring (FLR) may be provided instead of the JTE region 37. In addition, a configuration in which the JTE region 37 and the FLR are combined may be adopted.

The impurity concentration of the JTE region 37 selectively provided in the terminal well region 31 is lower than the impurity concentration of the terminal well region 31. Although not illustrated, a terminal trench may be provided in the terminal region, and the terminal well region 31 and the JTE region 37 may be provided at the bottom of the terminal trench. The depth of the terminal trench may be equal to or greater than the depth of a trench in the trench gate 4. The gate wire 82 may be provided on the terminal region. The source contact hole of the source electrode 80 may not be provided on the terminal region side of the end of the trench gate 4. That is, the source contact hole may not be provided in the region where the terminal well region 31 and the JTE region 37 are provided at the lower part of the terminal trench.

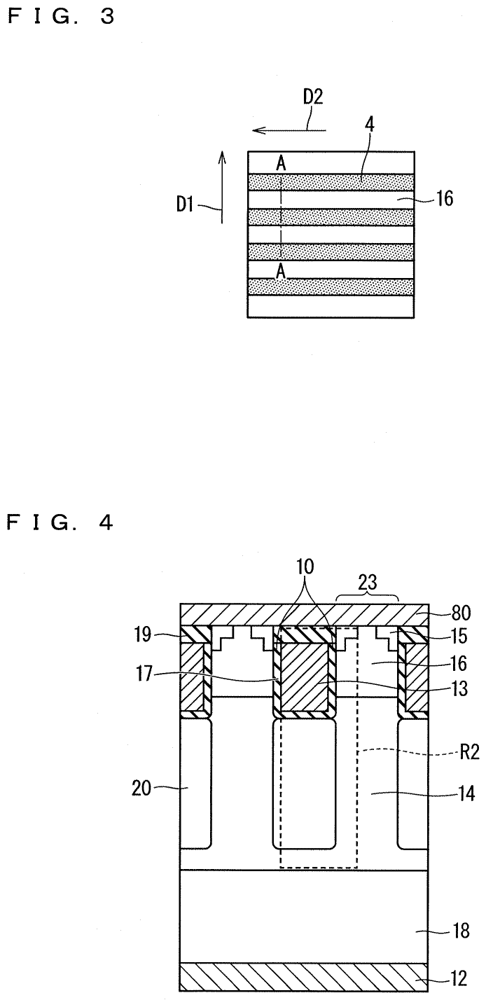

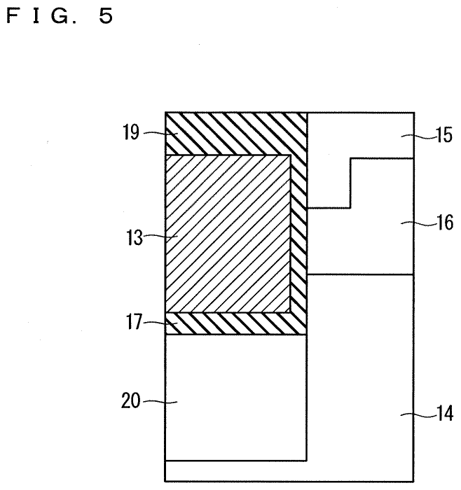

FIG. 3 is an enlarged view of a region R1 in FIG. 2. FIG. 4 is a cross-sectional view, taken along line A-A in FIG. 3. FIG. 5 is an enlarged view of a region R2 in FIG. 4. In the semiconductor device 101, a plurality of the trench gates 4 are arranged in a first direction D1 and extend in a second direction D2 in plan view, as illustrated in FIG. 3.

As illustrated in FIG. 4, the semiconductor device 101 is formed by including a semiconductor substrate 18, a drift layer 14, the base layer 16, a source layer 15, a gate insulating film 17, a gate electrode 13, an interlayer insulating film 19, the source electrode 80, and a drain electrode 12.

The n-type drift layer 14 is formed on the semiconductor substrate 18. The p-type base layer 16 is formed on the surface layer, on the side opposite to the semiconductor substrate 18, of the drift layer 14. The n-type source layer 15 is discretely formed on the surface layer, on the side opposite to the semiconductor substrate 18, of the base layer 16. The source layer 15 is also referred to as a channel formation layer. Of the surface layer of the base layer 16, a region, where the source layer 15 is not formed, will serve as a contact region.

The source electrode 80 is formed on the base layer 16, the source layer 15, and the interlayer insulating film 19 to be described later. The drain electrode 12 is formed on the side, opposite to the drift layer 14, of the semiconductor substrate 18.

A plurality of trenches 10, each of which penetrates the source layer 15 and the base layer 16 to reach the drift layer 14, are formed. The region between the plurality of trenches 10 is a mesa region 23. The base layer 16 and the source layer 15 are formed in the mesa region 23. In the surface of the mesa region 23, the area of the contact region is preferably smaller than the area of the source layer 15.

The gate insulating film 17, the gate electrode 13, and the interlayer insulating film 19 are embedded in the trench 10. The gate insulating film 17 is formed on the side surface and the bottom surface of the trench 10. The gate electrode 13 is formed on the gate insulating film 17. Therefore, the gate electrode 13 faces the base layer 16 via the gate insulating film 17.

In addition, a p-type electric field relaxation layer 20 is formed directly under the trench 10. By providing the electric field relaxation layer directly under the trench 10 to serve as the trench gate 4, an electric field to be applied to the gate insulating film 17 at the bottom of the trench 10 is relaxed, and the dielectric breakdown of the gate insulating film 17, possibly occurring when a high voltage is applied, is suppressed. Note that, compared to the case where the electric field relaxation layers 20 are provided directly under only a part of the trenches 10, the case, where the electric field relaxation layers 20 are provided directly under all of the trenches 10, is more highly effective. In particular, for a trench type MOSFET using silicon carbide that is required to operate under a higher voltage than that using Si, providing the electric field relaxation layers 20 is effective in suppressing the dielectric breakdown of the gate insulating film 17. In addition, the electric field relaxation layer 20 may be electrically connected to the source electrode 80 via the base layer 16. In that case, a connection layer of the second conductivity type that connects the electric field relaxation layer 20 and the base layer 16 may be provided in a part of the mesa region 23. The connection layer is preferably arranged directly under the contact region. The electric field relaxation layers 20 may extend in the same direction as the extending direction (the second direction D2 in FIG. 3) of the trenches 10 and may be provided alternately with the drift layers 14 or n-type pillar layers separately provided, thereby forming a super junction structure. The peak impurity concentration of the n-type pillar layer may be higher than that of the drift layer 14.

### A-2. Manufacturing Method

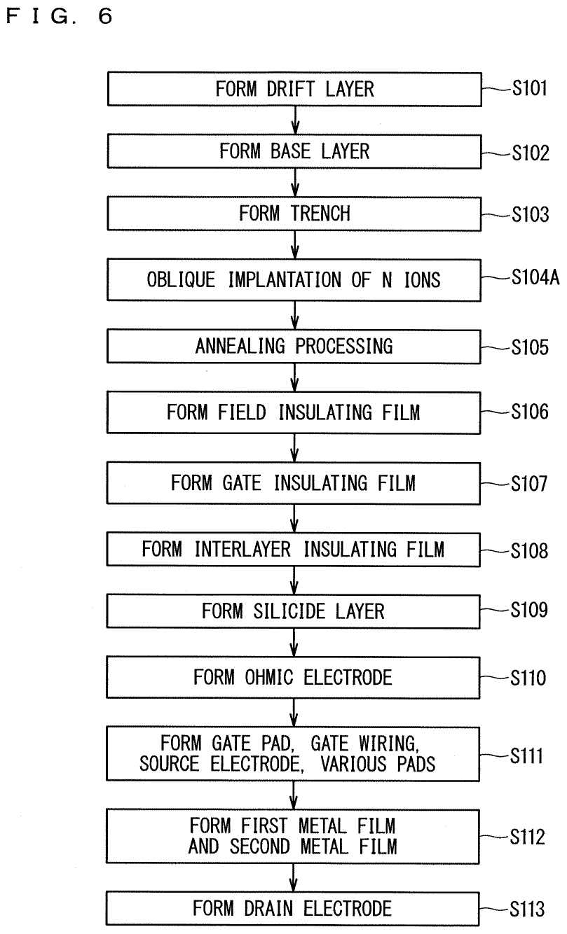

FIG. 6 is a flowchart illustrating a manufacturing process of the semiconductor device 101 according to the first preferred embodiment. Hereinafter, a method of manufacturing the semiconductor device 101 will be described according to the flow in FIG. 6.

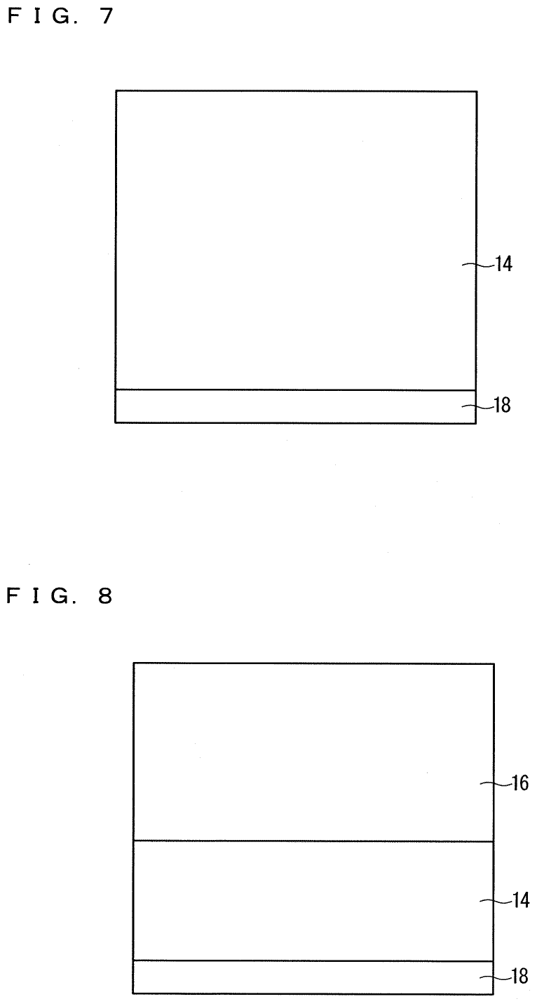

First, in a step S101, the drift layer 14 made of silicon carbide is epitaxially grown on the semiconductor substrate 18 made of n-type, low-resistance silicon carbide and having a 4H polytype, by a chemical vapor deposition (CVD) method. FIG. 7 illustrates this state. The plane orientation of the main surface of the semiconductor substrate 18, on which the drift layer 14 is epitaxially grown, is a (0001) plane having an off-angle. The impurity concentration of the drift layer 14 is set to be between 1×10¹⁵ cm⁻³ and 1×10¹⁷ cm⁻³ (inclusive). The thickness of the drift layer 14 is set to be between 5 μm and 50 μm (inclusive).

Next, in a step S102, the base layer 16 is formed on the drift layer 14. The processing of this step is also referred to as a base layer formation process. Specifically, Al as a p-type impurity is ion-implanted into the surface of the drift layer 14. At this time, the depth of Al ion implantation is set to be between about 0.5 μm and about 10 μm (inclusive), which does not exceed the thickness of the drift layer 14. Within a range between 1×10¹⁷ cm⁻³ and 1×10¹⁹ cm⁻³ (inclusive), the impurity concentration of the ion-implanted Al is set to be higher than the impurity concentration of the drift layer. The region implanted with Al ions by this process will serve as the base layer 16 in the active region and serve as the terminal well region 31 in the terminal region. FIG. 8 illustrates this state.

Note that the base layer 16 may be formed on the drift layer 14 by an epitaxial method. In addition, an implantation mask may be formed on the base layer 16 except for a predetermined location by photoresist or the like, Al may be ion-implanted at an impurity concentration within a range between 1×10¹⁸ cm⁻³ and 1×10²¹ cm⁻³ (inclusive) that is higher than the impurity concentration of the base layer 16, and then the implantation mask may be removed. Of the region into which Al is ion-implanted by this process, a region showing a p-type may serve as a p⁺-type contact layer by being activated by a heat treatment to be described later.

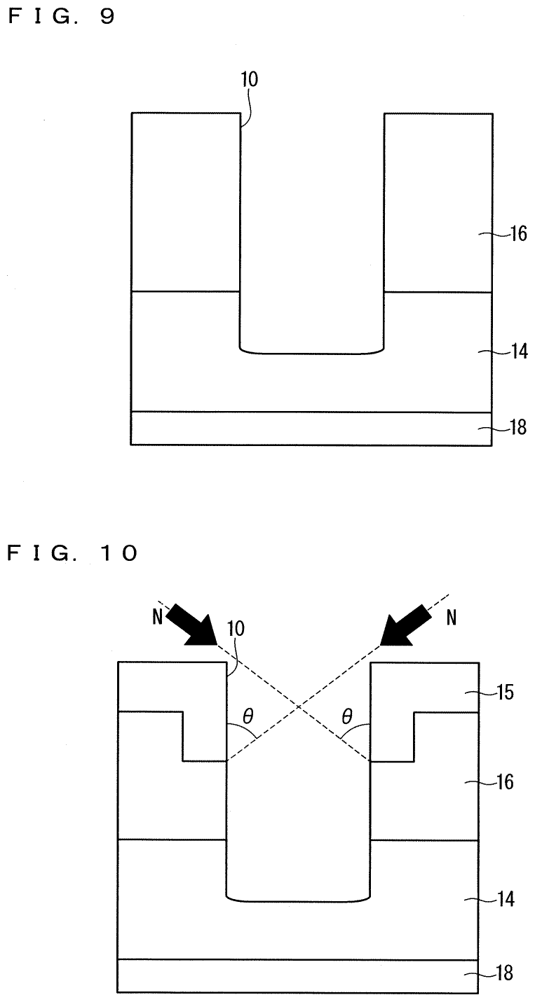

Next, in a step S103, the trench 10, which penetrates the base layer 16 to reach the drift layer 14, is formed by dry etching. The processing of this step is also referred to as a trench formation process. FIG. 9 illustrates this state. Specifically, an etching mask is deposited on the base layer 16 with a thickness between about 1 μm and about 5 μm (inclusive), and a resist mask made of a resist material is formed thereon. The resist mask is formed in a pattern, in which formation regions of the trenches 10 are opened, by a photolithography technique. When the trenches 10 are arranged in a stripe pattern, the resist mask is formed in a stripe-shaped pattern obtained by inverting the stripe pattern of the trenches. Then, the trench 10 that penetrates the base layer 16 is formed by reactive ion etching (RIE) processing using the resist mask as a mask.

The depth of the trench 10 is set to be equal to or more than the depth of the base layer 16 and between about 0.5 μm and about 3 μm (inclusive). Note that the terminal trench may be formed at the same time as the trench 10 is formed. When the plane orientation of the main surface of the semiconductor substrate 18, on which the drift layer 14 is epitaxially grown, is a (0001) plane having an off-angle in the <11-20> direction, the trench 10 may be formed parallel to the <11-20> direction. When done in this way, the threshold voltage of the MOSFET in the trench gate 4 is not affected in the off-direction of the semiconductor substrate 18, so that a variation in the threshold voltage of the MOSFET is reduced.

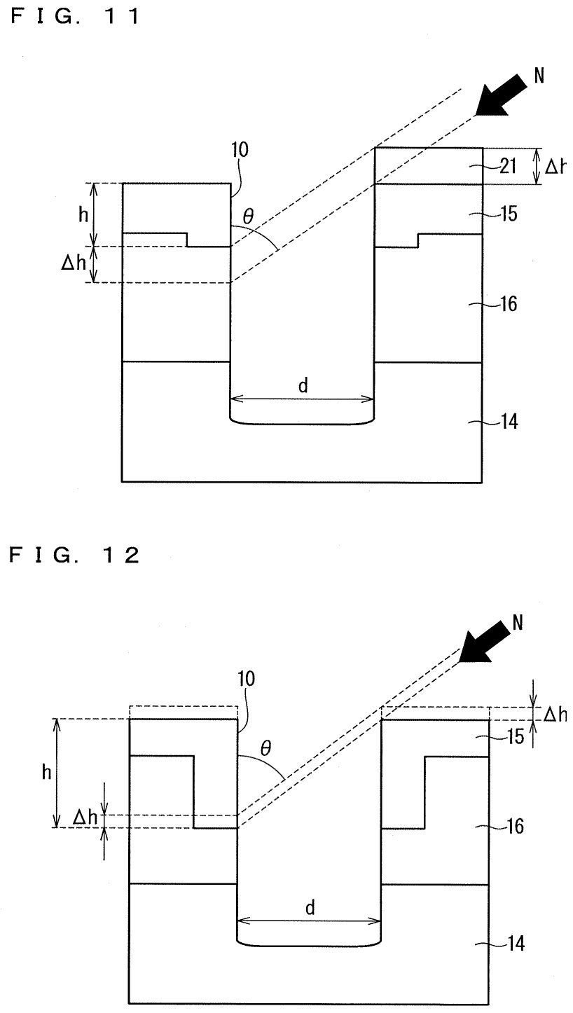

Next, in a step S104A, ions of n-type impurities, such as nitrogen (N), are implanted from an oblique direction having an angle θ with respect to the sidewall of the trench 10. Such ion implantation from an oblique direction is referred to as oblique ion implantation. The processing of this step is also referred to as a first oblique implantation process. FIG. 10 illustrates this state. The implantation energy is desirably set to be between 10 keV and 150 keV (inclusive). If the implantation energy exceeds 150 keV, the semiconductor wafer is easily warped. If it particularly exceeds 600 keV, the semiconductor wafer is more easily warped.

The impurity concentration of the ions implanted in this process is within a range between 1×10¹⁸ cm⁻³ and 1×10²¹ cm⁻³ (inclusive). Of the regions into which the impurities are implanted in this process, a region showing an n-type will serve as the source layer 15. With the oblique ion implantation, the source layer 15 is formed on a part of the surface layer of the base layer 16 and the sidewall of the trench 10. Therefore, the source layer 15 becomes deeper as it goes from the central side of the mesa region 23 to the sidewall side of the trench 10. As a result, the deep source layer 15 can be formed in a portion in contact with the sidewall of the trench 10 with small implantation energy. Therefore, warpage of the semiconductor wafer after the ion implantation is suppressed.

Hereinafter, the angle θ between the ion implantation direction and the sidewall of the trench 10 is referred to as an ion implantation angle θ. The relationship among the ion implantation angle θ, the width d of the trench 10, and the depth h of the source layer 15 in contact with the sidewall of the trench 10 is expressed by the following equation (1).

$$\begin{matrix}[ Mathematical Equation 1 ] & \\ d / h = tan θ & ( 1 )\end{matrix}$$

As can be seen from the equation (1), when it is assumed that the ion implantation angle θ is constant for all the trenches 10 and if the trench width d varies, the depth h of the source layer 15 also varies. The depth h of the source layer 15 is a channel length Lch. Therefore, if the trench width d varies, the channel length Lch varies. In a case where any two trenches 10 are selected from the plurality of trenches 10 and when the width of the first trench 10 is set to d1 and the width of the second trench 10 is set to d2, it is desirable that d2/d1 be between 0.8 and 1.2 (inclusive) from the viewpoint of suppressing the variation in the channel length Lch.

The ion implantation angle θ may be larger than 0° and equal to or smaller than 70°. If the ion implantation angle θ exceeds 70°, a shadow is formed by the upper corner of the trench 10 and an irradiation range is limited, that is, the influence of shadowing increases, making it undesirable. Note that, by the oblique implantation, the impurity concentration of the source layer 15 may become lower as it goes from the sidewall side of the trench 10 to the central side of the mesa region 23. Since the source layer 15 is formed in a direction different from the thickness direction of the semiconductor substrate 18, warpage of the semiconductor wafer is suppressed.

Three methods of further suppressing a variation in the channel length Lch will be described below. A first method is a method of adjusting the ion implantation angle θ in accordance with the width d of the trench 10. It is assumed that, regarding the widths d1 and d2 of the two trenches 10, d2/d1 is between 0.8 and 1.2 (inclusive), as described above. It is assumed that the ion implantation angle θ with respect to the trench 10 whose width is d1 is θ1 and the depth h of the source layer 15 formed adjacent to the trench 10 is h1. It is assumed that the ion implantation angle θ with respect to the trench 10 whose width is d2 is θ2 and the depth h of the source layer 15 formed adjacent to the trench 10 is h2. The following equation (2) is obtained by modifying the equation (1).

$$\begin{matrix}[ Mathematical Equation 2 ] & \\ \frac{d 2}{d 1} = \frac{h 2}{h 1} ( \frac{tan θ2}{tan θ 1} ) & ( 2 )\end{matrix}$$

In order to reduce the variation in the depth h of the source layer 15, that is, in order to satisfy h2/h1=1, θ2 may be varied in accordance with the variation in the width d of the trench 10, that is, the variation in d2/d1 such that tan θ2/tan θ1=d2/d1 is satisfied.

A second method is a method of adjusting the thickness of an oxide film mask at the time of the oblique implantation in accordance with the variation in the width d of the trench 10. In this method, after the base layer 16 is formed on the surface layer of the drift layer 14 and before the trench 10 is formed, the source layer 15 is formed on the surface layer of the base layer 16 by ion implantation using a mask. This process is also referred to as an ion implantation process. Thereafter, an oxide film mask 21 is formed on the source layer 15, and the trench 10 that penetrates the base layer 16 is formed by dry etching using the oxide film mask 21.

Next, the thickness of the oxide film mask 21 is adjusted to Δh. This process is also referred to as a mask thickness adjustment process.

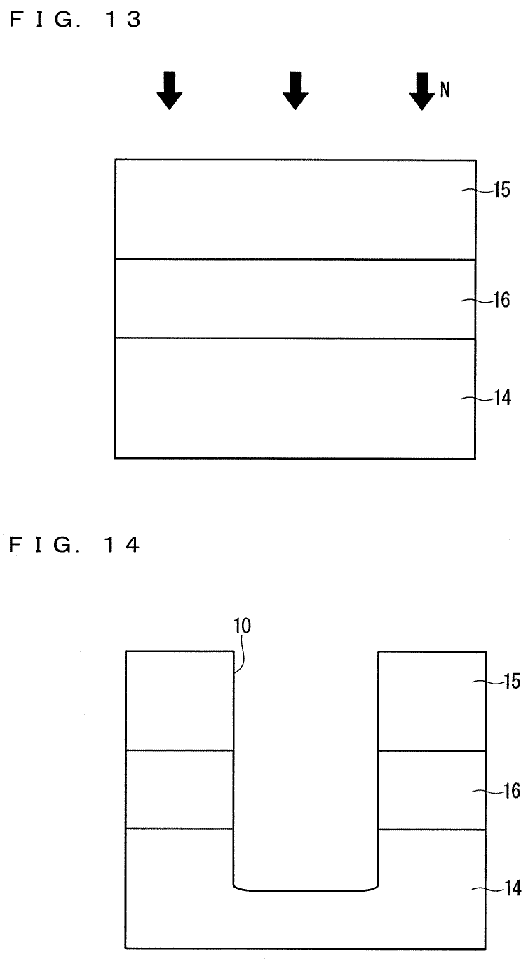

Thereafter, the oblique ion implantation is performed at the implantation angle θ with respect to the sidewall of the trench 10 while leaving the oxide film mask 21 having the thickness Δh in place, thereby forming the source layer 15 on the sidewall of the trench 10. FIG. 11 illustrates this state. Note that illustration of the semiconductor substrate 18 is omitted in FIG. 11, and the same applies to the cross-sectional views of FIG. 12 and the subsequent drawings. When the oblique ion implantation is performed in a state where the oxide film mask 21 having the thickness Δh is left in place, the depth h of the source layer 15 becomes smaller by Δh as compared to the oblique ion implantation without the oxide film mask 21. Therefore, the depth h of the source layer 15 can be adjusted by determining how much thickness of the oxide film mask 21 is left in the mask thickness adjustment process. That is, the thickness of the oxide film mask 21 to be adjusted in the mask thickness adjustment process is determined according to the width of the trench 10 adjacent to the oxide film mask 21. For example, in a case where the width d of the trench 10 is larger than a reference value, the remaining thickness of the oxide film mask 21 is increased by that amount, whereby the variation in the depth h of the source layer 15 can be suppressed.

A third method is a method of adjusting, before the oblique ion implantation, the etching amount of a SiC surface according to the width d of the trench 10. First, the base layer 16 is formed on the drift layer 14. Next, ion implantation is performed on the surface layer of the base layer 16 using an implantation mask to form the source layer 15. Thereafter, the trench 10, which penetrates the source layer 15 and the base layer 16, is formed by dry etching. Next, an etching process is performed in which the surface layer of the source layer 15, that is, the SiC surface is etched by Δh to reduce the depth of the trench 10. The etching amount Δh of the source layer 15 is determined according to the width d of the trench 10 to which the source layer 15 is adjacent.

Thereafter, the source layer 15 is formed on the sidewall of the trench 10 by the oblique ion implantation. FIG. 12 illustrates this state. The relationship between the width d of the trench and the depth h of the source layer 15 is as shown in the equation (1). Therefore, if the width d of the trench varies, the etching amount Δh of the SiC surface is adjusted, whereby the depth of the source layer 15 can be adjusted. When the etching amount of the SiC surface is set to Δh, the depth of the source layer 15 increases by Δh, which can reduce the variation in the depth of the source layer 15.

After various impurities are introduced by ion implantation as described above, an annealing treatment is performed in a step S105 to diffuse and activate the impurities in the base layer 16, the source layer 15, and the like. For example, the semiconductor substrate is annealed at a temperature of 1300° C. to 1900° C. for 30 seconds to 1 hour in an inert gas atmosphere, such as argon (Ar) gas, by a heat treatment apparatus. By this annealing, ion-implanted impurities, such as N and Al, are electrically activated. In the present preferred embodiment, the heat treatment is performed after all of the impurities are implanted. However, the present invention is not limited thereto, and for example, implantation of impurities and a heat treatment for diffusion and activation may be alternately performed.

Next, in a step S106, an insulating film, which will serve as the field insulating film (not illustrated), is formed on the front surface side of the semiconductor substrate 18. The insulating film may be formed by thermal oxidation or the like, or may be formed by a deposition method (deposition). The thickness of the insulating film is determined in consideration of the cleaning in the subsequent process and a loss in the etching process. The field insulating film made of silicon oxide is formed on regions (e.g., a region of the gate pad, a region of the sensing pad, and the terminal region) excluding the active region corresponding to the base layer by using, for example, a CVD method or a photolithography technique. The film thickness of the field insulating film is, for example, between 0.5 μm and 2 μm, which is larger than the film thickness of the gate insulating film 17 to be described next.

Thereafter, in a step S107, the trench 10 not covered with the field insulating film is thermally oxidized, and a silicon oxide film having a desired thickness is formed as the gate insulating film 17 on the sidewall and the bottom surface inside the trench. Note that the method of forming the gate insulating film 17 and the material thereof are not limited thereto. Thereafter, a conductive polycrystalline silicon film is formed on the gate insulating film 17 and the field insulating film by a low-pressure CVD method, and is patterned to form the gate electrode 13 inside the trench 10. Note that the method of forming the gate electrode 13 and the material thereof are not limited thereto.

Next, in a step S108, an insulating film, having a film thickness larger than that of the gate insulating film 17 and made of silicon oxide, is formed as the interlayer insulating film 19 on the front surface side of the semiconductor substrate 18 by a low-pressure CVD method. The interlayer insulating film may be boro-phospho silicate glass (BPSG) containing boron (B) or phosphorus (P), or may be a laminated film of BPSG and silicon oxide without impurities. Next, the interlayer insulating film 19 deposited is etched. As a result, the interlayer insulating film 19 remains on the gate electrode 13 formed in the trench 10, and does not remain in the mesa region 23 around the trench 10.

Next, in a step S109, a silicide layer is formed on the entire front surface side of the semiconductor substrate 18. Specifically, a metal film (e.g., a Ni film) containing Ni as a main component is formed on the entire front surface side of the semiconductor substrate 18 by, for example, a sputtering method. Then, a heat treatment is performed at a temperature of 600° C. to 1100° C. to react the metal film containing Ni as a main component with the semiconductor substrate, without the insulating film, from which SiC is exposed, thereby forming the silicide layer therebetween.

Thereafter, in a step S110, the metal film containing Ni as a main component remaining on the interlayer insulating film 19 and the like is removed by wet etching using sulfuric acid/hydrogen peroxide mixture or the like to form an ohmic electrode.

Then, in a step S111, a metal film containing Al or AlSi is formed on the entire front surface side of the semiconductor substrate 18 by, for example, sputtering, a mask having a mask pattern is formed using a photoengraving technique, and the metal film deposited is etched. As a result, the gate pad 81 and the gate wire 82 that are in contact with the gate electrode, the source electrode, and various pads are formed.

Next, in a step S112, a first metal film and a second metal film are formed. Specifically, a polyimide film (not illustrated) is formed on the source electrode 80, a mask having a mask pattern is formed using a photoengraving technique, and the polyimide film is etched. Then, an electroless plating film containing Ni or a Ni compound is formed as the first metal film on the source electrode 80 on which no polyimide film is provided. Finally, an electroless plating film containing Au for preventing oxidation of the first metal film is formed as the second metal film on the first metal film. Note that the first metal film and the second metal film may be formed by sputtering or the like instead of electroless plating.

Thereafter, in a step S113, a metal film containing Ni or Au is formed on the entire back surface side of the semiconductor substrate 18 by, for example, sputtering to form the drain electrode 12, similarly to the formation of the source electrode 80.

### A-3. Comparative Example

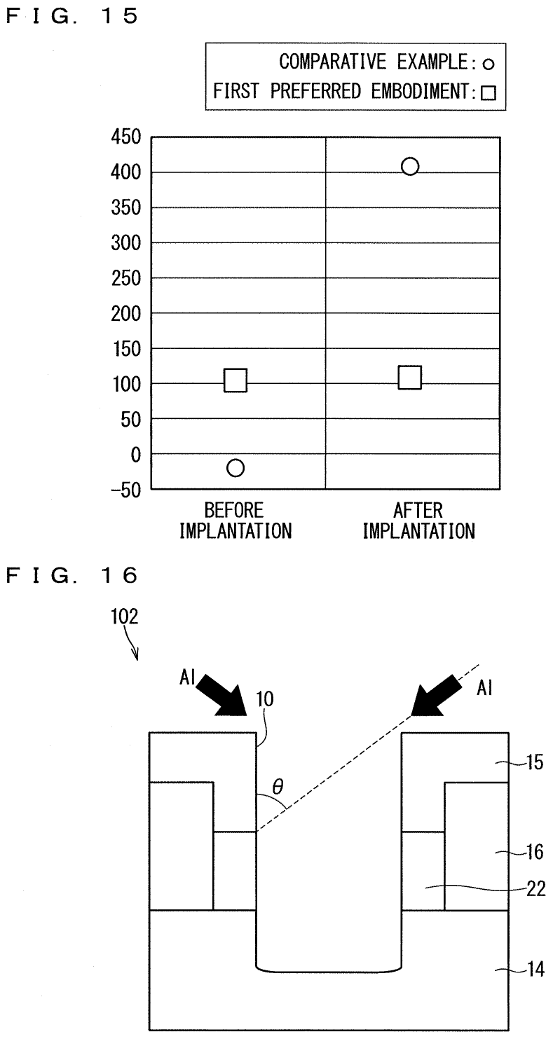

FIGS. 13 and 14 are cross-sectional views illustrating a method of manufacturing a semiconductor device of a comparative example. According to the manufacturing method of the comparative example, the drift layer 14 is formed on the semiconductor substrate 18. Then, the base layer 16 is formed on the surface layer, on the side opposite to the semiconductor substrate 18, of the drift layer 14. Thereafter, N ions are implanted into the surface layer, on the side opposite to the drift layer 14, of the base layer 16 to form the source layer 15, as illustrated in FIG. 13.

Next, the trench 10 that penetrates, from the upper surface of the source layer 15, the source layer 15 and the base layer 16 to reach the drift layer 14 is formed, as illustrated in FIG. 14.

In the comparative example, the direction of ion implantation for forming the source layer 15 is the thickness direction of the semiconductor substrate 18, that is, a direction perpendicular to the main surface of the semiconductor substrate 18. Therefore, the implantation region of the source layer 15 cannot be suppressed in the thickness direction of the semiconductor substrate 18. As a result, warpage occurs in the semiconductor wafer after the ion implantation for forming the source layer 15.

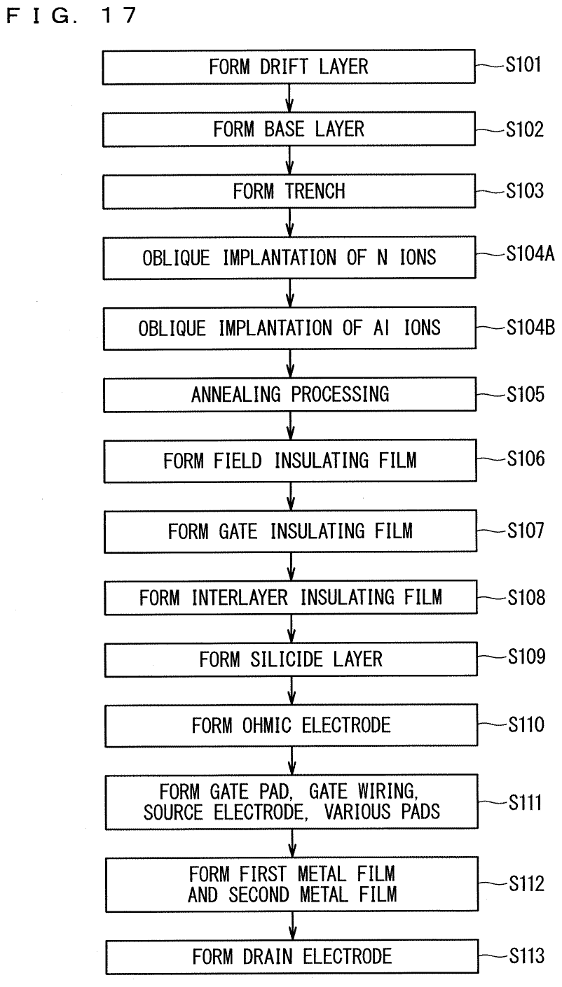

FIG. 15 is a view in which the amounts of warpage of the semiconductor wafers before and after the ion implantation for forming the source layer 15 are compared between the method of manufacturing a semiconductor device of the comparative example and that of the present preferred embodiment. In FIG. 15, circles indicate the amounts of warpage of the semiconductor wafer by the manufacturing method of the comparative example, and squares indicate the amounts of warpage of the semiconductor wafer by the manufacturing method of the present preferred embodiment. It can be seen from FIG. 15 that the warpage becomes large after the ion implantation in the comparative example, but the manufacturing method of the present preferred embodiment can suppress the amount of warpage after the ion implantation. In the present preferred embodiment, the amount of warpage of the semiconductor wafer can be suppressed, for example, to 25% or less of that in the comparative example.

### A-4. Effects

As described above, the semiconductor device 101 according to the first preferred embodiment includes the drift layer 14, the base layer 16 of the second conductivity type, the channel formation layer of the first conductivity type, and the gate electrode 13. The base layer 16 is formed on a part of the surface layer of the drift layer 14. The channel formation layer is formed on a part of the surface layer of the base layer 16. The gate electrode 13 is provided in a plurality of the trenches 10, each penetrating the channel formation layer and the base layer 16, via an insulating film. The channel formation layer formed between the plurality of the trenches 10 is shallower and has a lower impurity concentration as being farther from the sidewall of each of the plurality of the trenches 10. Such a channel formation layer can be formed with low implantation energy by performing ion implantation from an oblique direction with respect to the sidewall of the trench 10. Therefore, warpage of the semiconductor wafer can be suppressed after the ion implantation for forming the channel formation layer. In addition, the channel formation layer can be formed up to a deep position while warpage of the semiconductor wafer is suppressed, and thus the thickness of the interlayer insulating film 19 to be embedded in the trench 10 can be increased. Therefore, the margin of the interlayer insulating film 19 with respect to a variation in the depth of the gate electrode 13 in the trench 10 can be increased, whereby reliability can be improved.

The manufacturing method of the semiconductor device 101 according to the first preferred embodiment includes a base layer formation process, a trench formation process, and a first oblique implantation process. In the base layer formation process, impurity ions are implanted into the drift layer 14 to form the base layer 16 of the second conductivity type on the surface layer of the drift layer 14. In the trench formation process, the plurality of the trenches 10, each of which penetrates the base layer 16, are formed. In the first oblique implantation process, impurity ions are implanted from an oblique direction forming an angle θ with respect to the sidewall of each of the plurality of the trenches 10 to form the channel formation layer of the first conductivity type on the surface layer of the base layer 16. In the first oblique implantation process, the channel formation layer is formed on the sidewall of the trench 10, and thus the channel formation layer can be formed deep even with low implantation energy. Therefore, warpage of the semiconductor wafer after the first oblique implantation process can be suppressed. In addition, the channel formation layer can be formed up to a deep position while warpage of the semiconductor wafer is suppressed, and thus the thickness of the interlayer insulating film 19 to be embedded in the trench 10 can be increased. Therefore, the margin of the interlayer insulating film 19 with respect to a variation in the depth of the gate electrode 13 in the trench 10 can be increased, whereby reliability can be improved.

### B. Second Preferred Embodiment

FIG. 16 is a cross-sectional view schematically illustrating a configuration of a semiconductor device 102 according to a second preferred embodiment. The semiconductor device 102 is different from the semiconductor device 101 according to the first preferred embodiment in that a P-type well layer 22 is provided in a region under the source layer 15 along the sidewall of the trench 10. The well layer 22 is also referred to as a well layer. The well layer 22 is adjacent to the source layer 15 from below and is in contact with the sidewall of the trench 10.

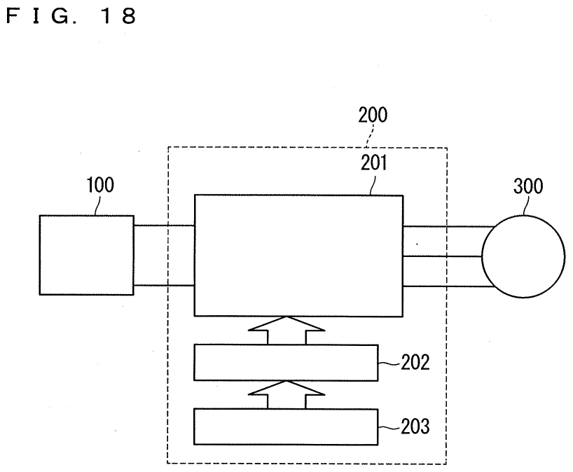

FIG. 17 is a flowchart illustrating a manufacturing process of the semiconductor device 102. In the manufacturing method of the semiconductor device 102, oblique implantation of N ions for forming the source layer 15 (step S104A) is performed, and then oblique implantation of Al ions for forming the well layer 22 (step S104B) is performed. This oblique implantation process of Al ions is also referred to as a second oblique implantation process.

In the semiconductor device 101 according to the first preferred embodiment without the well layer 22, if the width d of the trench 10 varies due to a manufacturing error or the like, the depth h of the source layer 15 varies in a case where the ion implantation angle θ is the same, which also causes a variation in the channel length Lch. In the semiconductor device 102 including the well layer 22 formed by the second ion implantation, however, the channel length Lch is fixed, so that a variation in the electrical characteristics caused by the variation in the channel length Lch is suppressed, whereby high reliability can be obtained.

### C. Third Preferred Embodiment

In the present preferred embodiment, the semiconductor device 101,102 according to any one of the above-described first and second preferred embodiments is applied to a power conversion apparatus. Although the application of the semiconductor device 101,102 is not limited to a specific power conversion apparatus, a case, where the semiconductor device 101,102 is applied to a three-phase inverter, will be described below as a third preferred embodiment.

FIG. 18 is a block diagram illustrating a configuration of a power conversion system to which a power conversion apparatus 200 according to the present preferred embodiment is applied. The power conversion system illustrated in FIG. 18 includes a power supply 100, the power conversion apparatus 200, and a load 300. The power supply 100 is a DC power supply, which supplies DC power to the power conversion apparatus 200. The power supply 100 can include various elements. For example, the power supply 100 may include a DC system, a solar cell, or a storage battery, or may include a rectifier circuit or an AC/DC converter connected to an AC system. In addition, the power supply 100 may include a DC/DC converter that converts DC power output from the DC system into predetermined power.

The power conversion apparatus 200 is a three-phase inverter connected between the power supply 100 and the load 300. The power conversion apparatus 200 converts the DC power supplied from the power supply 100 into AC power and supplies the AC power to the load 300. As illustrated in FIG. 18, the power conversion apparatus 200 includes a main conversion circuit 201, a drive circuit 202, and a control circuit 203. The main conversion circuit 201 converts DC power into AC power and outputs the AC power. The drive circuit 202 outputs a drive signal for driving each switching element of the main conversion circuit 201. The control circuit 203 outputs a control signal for controlling the drive circuit 202 to the drive circuit 202.

The load 300 is a three-phase electric motor to be driven by the AC power supplied from the power conversion apparatus 200. Note that the load 300 is not limited to a specific application and is an electric motor to be mounted on various electrical equipment. For example, the load 300 is used as an electric motor for a hybrid car, an electric car, a railway vehicle, an elevator, or air conditioning equipment.

Hereinafter, details of the power conversion apparatus 200 will be described. The main conversion circuit 201 includes the switching elements and freewheeling diodes (not illustrated), converts the DC power supplied from the power supply 100 into AC power by switching of the switching elements, and supplies the AC power to the load 300. Although there are various specific circuit configurations of the main conversion circuit 201, the main conversion circuit 201 according to the present preferred embodiment is a two-level three-phase full bridge circuit, and can include six switching elements and six freewheeling diodes antiparallel to the respective switching elements. The semiconductor device 101,102 according to any one of the first and second preferred embodiments described above is applied to each switching element of the main conversion circuit 201. The six switching elements are connected in series for every two switching elements to constitute upper and lower arms, and each of the upper and lower arms constitutes each phase (U-phase, V-phase, W-phase) of the full bridge circuit. The output terminals of each of the upper and lower arms, that is, the three output terminals of the main conversion circuit 201 are connected to the load 300.

The drive circuit 202 generates a drive signal for driving the switching elements of the main conversion circuit 201, and supplies the drive signal to control electrodes of the switching elements of the main conversion circuit 201. Specifically, the drive circuit 202 outputs a drive signal for turning on the switching element and a drive signal for turning off the switching element to the control electrode of each switching element in accordance with the control signal from the control circuit 203 to be described later. When the switching element is maintained in an ON state, the drive signal is a voltage signal (ON signal) equal to or higher than the threshold voltage of the switching element. When the switching element is maintained in an OFF state, the drive signal is a voltage signal (OFF signal) equal to or lower than the threshold voltage of the switching element.

The control circuit 203 controls the switching elements of the main conversion circuit 201 so that desired power is supplied to the load 300. Specifically, the control circuit 203 calculates a time (on time) during which each switching element of the main conversion circuit 201 is to be turned on, on the basis of the power to be supplied to the load 300. For example, the main conversion circuit 201 can be controlled by PWM control that modulates the ON time of the switching element depending on the voltage to be output. Then, the control circuit 203 outputs control commands (control signals) to the drive circuit 202 so that the ON signal is output to the switching element to be turned on at each time point and the OFF signal is output to the switching element to be turned off at the time point. The drive circuit 202 outputs the ON signal or the OFF signal as the drive signal to the control electrode of each switching element according to the control signal.

In the power conversion apparatus according to the present preferred embodiment, the semiconductor device 101,102 according to any one of the first and second preferred embodiments is applied as the switching element of the main conversion circuit 201, so that warpage of the semiconductor wafer is reduced, whereby reliability can be improved.

In the present preferred embodiment, an example has been described in which the semiconductor device 101,102 is applied to the two-level three-phase inverter, but the semiconductor device 101,102 is not limited thereto and can be applied to various power conversion apparatuses. In the present embodiment, the two-level power conversion apparatus is used, but a three-level or multi-level power conversion apparatus may be used, or in a case where power is supplied to a single-phase load, the semiconductor device 101,102 may be applied to a single-phase inverter. In a case where power is supplied to a DC load or the like, the semiconductor device 101,102 can also be applied to a DC/DC converter or an AC/DC converter.

In addition, the power conversion apparatus, to which the semiconductor device 101,102 is applied, is not limited to the case where the above-described load is an electric motor, and can be used, for example, as a power supply apparatus of an electric discharge machine, a laser processing machine, an induction cooker, or a contactless power supply system, and further can also be used as a power conditioner of a solar power generation system, an energy storage system, or the like.

Although the preferred embodiments and the like have been described in detail above, the present invention is not limited to the above-described preferred embodiments and the like, and various modifications and substitutions can be made to the above-described preferred embodiments and the like without departing from the scope described in the claims.

Hereinafter, various aspects of the present disclosure will be collectively described as Appendices.

### (Appendix 1)

A semiconductor device comprising:
a drift layer;
a base layer of a second conductivity type formed on a part of a surface layer of the drift layer;
a channel formation layer of a first conductivity type formed on a part of a surface layer of the base layer; and
a gate electrode provided in a plurality of trenches, each penetrating the channel formation layer and the base layer, via a gate insulating film, wherein
the channel formation layer formed between the plurality of trenches is shallower and has a lower impurity concentration as being farther from a sidewall of each of the plurality of trenches.

### (Appendix 2)

The semiconductor device according to Appendix 1, further comprising a well layer adjacent to the channel formation layer from below and in contact with the sidewall of each of the plurality of trenches.

### (Appendix 3)

A method of manufacturing a semiconductor device, the method comprising:
a base layer formation process of implanting impurity ions into a drift layer to form a base layer of a second conductivity type on the drift layer;
a trench formation process of forming a plurality of trenches each of which penetrates the base layer; and
a first oblique implantation process of implanting impurity ions from an oblique direction forming an angle θ with respect to a sidewall of each of the plurality of trenches to form a channel formation layer of a first conductivity type in at least a portion, in contact with the sidewall of each of the plurality of trenches, of the base layer.

### (Appendix 4)

The method of manufacturing a semiconductor device according to Appendix 3, wherein implantation energy of the impurity ions in the first oblique implantation process is between 10 keV and 150 keV (inclusive).

### (Appendix 5)

The method of manufacturing a semiconductor device according to Appendix 3 or 4, wherein when it is assumed that widths of a first trench and a second trench, arbitrarily selected from the plurality of trenches, are d1 and d2, respectively, d2/d1 is between 0.8 and 1.2 (inclusive).

### (Appendix 6)

The method of manufacturing a semiconductor device according to any one of Appendices 3 to 5, wherein in the first oblique implantation process, the angle θ is 70° or less.

### (Appendix 7)

The method of manufacturing a semiconductor device according to Appendix 5, wherein in the first oblique implantation process, when it is assumed that the angles θ with respect to the first trench and the second trench are θ1 and θ2, respectively, tan θ2/tan θ1=d2/d1 holds.

### (Appendix 8)

The method of manufacturing a semiconductor device according to any one of Appendices 3 to 6, the trench formation process being a process of forming the plurality of trenches using an oxide film mask, the method further comprising:
between the base layer formation process and the trench formation process, an ion implantation process of forming the channel formation layer on a surface layer of the base layer by ion implantation; and
between the trench formation process and the first oblique implantation process, a mask thickness adjustment process of adjusting a thickness of the oxide film mask, wherein
the thickness of the oxide film mask after being adjusted is determined according to a width of each of the plurality of trenches adjacent to the oxide film mask.

### (Appendix 9)

The method of manufacturing a semiconductor device according to any one of Appendices 3 to 6, the method further comprising:
between the base layer formation process and the trench formation process, an ion implantation process of forming the channel formation layer on a surface layer of the base layer by ion implantation; and
after the trench formation process, an etching process of etching a surface layer of the channel formation layer, wherein
an etching amount of the channel formation layer in the etching process is determined according to a width of the trench to which the channel formation layer is adjacent.

### (Appendix 10)

The method of manufacturing a semiconductor device according to any one of Appendices 3 to 9, the method further comprising after the first oblique implantation process, a second oblique implantation process of implanting impurity ions from an oblique direction with respect to the sidewall of each of the plurality of trenches to form a well layer of the second conductivity type in a region, in contact with the plurality of trenches, of the base layer.

### (Appendix 11)

A power conversion apparatus comprising:
a main conversion circuit that includes the semiconductor device according to Appendix 1 or 2 and converts input power to output converted power,
a drive circuit that outputs a drive signal for driving the semiconductor device to the semiconductor device; and
a control circuit that outputs a control signal for controlling the drive circuit to the drive circuit.

While the disclosure has been shown and described in detail, the foregoing description is in all aspects illustrative and not restrictive. It is therefore understood that numerous modifications and variations can be devised.

What is claimed is:

1. A semiconductor device comprising:
a drift layer;
a base layer of a second conductivity type formed on a part of a surface layer of the drift layer;
a channel formation layer of a first conductivity type formed on a part of a surface layer of the base layer; and
a gate electrode provided in a plurality of trenches, each penetrating the channel formation layer and the base layer, via a gate insulating film, wherein
the channel formation layer formed between the plurality of trenches is shallower and has a lower impurity concentration as being farther from a sidewall of each of the plurality of trenches.

2. The semiconductor device according to claim 1, further comprising a well layer adjacent to the channel formation layer from below and in contact with the sidewall of each of the plurality of trenches.

3. A method of manufacturing a semiconductor device, the method comprising:
a base layer formation process of implanting impurity ions into a drift layer to form a base layer of a second conductivity type on the drift layer;
a trench formation process of forming a plurality of trenches each of which penetrates the base layer; and
a first oblique implantation process of implanting impurity ions from an oblique direction forming an angle θ with respect to a sidewall of each of the plurality of trenches to form a channel formation layer of a first conductivity type in at least a portion of the base layer in contact with the sidewall of each of the plurality of trenches.

4. The method of manufacturing a semiconductor device according to claim 3, wherein implantation energy of the impurity ions in the first oblique implantation process is between 10 keV and 150 keV (inclusive).

5. The method of manufacturing a semiconductor device according to claim 3, wherein when it is assumed that widths of a first trench and a second trench, arbitrarily selected from the plurality of trenches, are d1 and d2, respectively, d2/d1 is between 0.8 and 1.2 (inclusive).

6. The method of manufacturing a semiconductor device according to claim 3, wherein in the first oblique implantation process, the angle θ is 70° or less.

7. The method of manufacturing a semiconductor device according to claim 5, wherein in the first oblique implantation process, when it is assumed that the angles θ with respect to the first trench and the second trench are θ1 and θ2, respectively, tan θ2/tan θ1=d2/d1 holds.

8. The method of manufacturing a semiconductor device according to claim 3, the trench formation process being a process of forming the plurality of trenches using an oxide film mask, the method further comprising:
between the base layer formation process and the trench formation process, an ion implantation process of forming the channel formation layer on a surface layer of the base layer by ion implantation; and
between the trench formation process and the first oblique implantation process, a mask thickness adjustment process of adjusting a thickness of the oxide film mask, wherein
the thickness of the oxide film mask after being adjusted is determined according to a width of each of the plurality of trenches adjacent to the oxide film mask.

9. The method of manufacturing a semiconductor device according to claim 3, the method further comprising:
between the base layer formation process and the trench formation process, an ion implantation process of forming the channel formation layer on a surface layer of the base layer by ion implantation; and
after the trench formation process, an etching process of etching a surface layer of the channel formation layer, wherein
an etching amount of the channel formation layer in the etching process is determined according to a width of the trench to which the channel formation layer is adjacent.

10. The method of manufacturing a semiconductor device according to claim 3, the method further comprising after the first oblique implantation process, a second oblique implantation process of implanting impurity ions from an oblique direction with respect to a sidewall of each of the plurality of trenches to form a well layer of the second conductivity type in a region, in contact with the plurality of trenches, of the base layer.

11. A power conversion apparatus comprising:
a main conversion circuit that includes the semiconductor device according to claim 1 and converts input power to output converted power;
a drive circuit that outputs a drive signal for driving the semiconductor device to the semiconductor device; and
a control circuit that outputs a control signal for controlling the drive circuit to the drive circuit.
